(19) United States
(12) Patent Application Publication
(10) Pub. No.: US 2025/0379466 A1
(43) Pub. Date: Dec. 11, 2025

(54) METHOD AND APPARATUS FOR CHARGING AND DISCHARGING LITHIUM-ION BATTERY

(71) Applicant: UIF (University Industry Foundation), Yonsei University, Seoul (KR)

(72) Inventors: Yong-June SHIN, Seoul (KR); Seong Jin JEONG, Changwon-si (KR); Hyeong Min LEE, Seoul (KR); Young Soo KIM, Seoul (KR)

(73) Assignee: UIF (University Industry Foundation), Yonsei University, Seoul (KR)

(21) Appl. No.: 19/226,740

(22) Filed: Jun. 3, 2025

(30) Foreign Application Priority Data
Jun. 5, 2024 (KR) 10-2024-0073779

(51) Int. Cl. H02J 7/00; G01R 31/385; H01M 10/0525; H01M 10/44; H01M 10/48

(52) U.S. Cl. CPC H02J 7/007182; G01R 31/385; H01M 10/0525; H01M 10/44; H01M 10/48; H01M 2220/20

(57) ABSTRACT

The charging and discharging operation method of a lithium-ion battery according to the present disclosure comprises measuring an overpotential for each discharge voltage while discharging the lithium-ion battery, determining a minimum discharge voltage for controlling charging and discharging based on a measurement result of the overpotential and controlling charging and discharging the lithium-ion battery according to the determined minimum discharge voltage.

### CROSS-REFERENCE TO RELATED APPLICATIONS

This application claims the priority benefit of Korean Patent Application No. 10-2024-0073779 filed on Jun. 5, 2024, in the Korean Intellectual Property Office, the disclosures of which are incorporated herein by reference.

### BACKGROUND

### 1. Field

The present disclosure relates to a method and an apparatus for charging and discharging a lithium-ion battery.

### 2. Description of the Related Art

Batteries for smartphones or electric vehicles are arbitrarily charged and discharged depending on the user, but batteries for submarines operate charging and discharging in accordance with a relatively consistent pattern, based on the mission plan and the patrol patterns of both enemy and friendly forces. Until recently, lead sulfate batteries have been used as batteries for submarines, but the introduction of lithium-ion batteries (tentative 2027) is being promoted in consideration of energy density according to the business decision of the Defense Acquisition Program Administration in 2017.

With the introduction of lithium-ion batteries, the energy density increases by about three times to 150 Wh/kg compared to the existing lead sulfate battery (45 Wh/kg). In addition, lead sulfate batteries can no longer be used due to a rapid decrease in battery life due to irreversible reaction when discharging less than 50% of state of charge (SOC), but lithium-ion batteries can be charged and discharged in a relatively wide SOC range of SOC up to 7 to 97%. If it is possible to determine the charging/discharging section in which the aging of the battery may be minimized by considering the increased battery capacity and SOC operation section when introducing the lithium-ion battery of the next-generation submarine, it is possible to reduce the defense budget for about 30 years by adjusting the depot maintenance cycle of the submarine in consideration of the battery life.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

The present disclosure has been made in an effort to provide a method and an apparatus for charging and discharging a lithium-ion battery, which are capable of determining a charging/discharging section where aging of the lithium-ion battery can be minimized, and performing charging and discharging according to the determined section.

The object to be solved of the present disclosure is not limited to the above-mentioned object, and other objects not mentioned will be clearly understood by those skilled in the art from the following description.

The charging and discharging operation method of a lithium-ion battery according to the present disclosure for solving the technical problem comprises measuring an overpotential for each discharge voltage while discharging the lithium-ion battery, determining a minimum discharge voltage for controlling charging and discharging based on a measurement result of the overpotential and controlling charging and discharging the lithium-ion battery according to the determined minimum discharge voltage.

The measuring an overpotential comprises discharging the lithium-ion battery using pulse discharge.

The measuring an overpotential comprises discharging the lithium-ion battery to a corresponding discharge voltage using pulse discharge, measuring an open-circuit-voltage (OCV) after a predetermined rest time and measuring the overpotential based on the difference between the corresponding discharge voltage and the OCV.

The determining a minimum discharge voltage comprises calculating an average of overpotentials measured up to a corresponding discharge voltage for each discharge voltage and determining a discharge voltage at which the average of the overpotentials is minimized as the minimum discharge voltage for controlling charging and discharging.

The lithium-ion battery is a lithium-ion battery for a submarine.

The lithium-ion battery is a lithium-ion battery for an energy storage system (ESS).

The charging and discharging operation apparatus of a lithium-ion battery according to the present disclosure for solving the technical problem comprises an overpotential measuring processor configured to measure an overpotential for each discharge voltage while discharging the lithium-ion battery, a minimum discharge voltage determining processor configured to determine a minimum discharge voltage for controlling charging and discharging based on a measurement result of the overpotential and a charging and discharging controller configured to control charging and discharging the lithium-ion battery according to the determined minimum discharge voltage.

The overpotential measuring processor is configured to discharge the lithium-ion battery using pulse discharge.

The overpotential measuring processor is configured to discharge the lithium-ion battery to a corresponding discharge voltage using pulse discharge, measure an open-circuit-voltage (OCV) after a predetermined rest time, and measure the overpotential based on the difference between the corresponding discharge voltage and the OCV.

The minimum discharge voltage determining processor is configured to calculate an average of overpotentials measured up to a corresponding discharge voltage for each discharge voltage, and determine a discharge voltage at which the average of the overpotentials is minimized as the minimum discharge voltage for controlling charging and discharging.

The lithium-ion battery is a lithium-ion battery for a submarine.

The lithium-ion battery is a lithium-ion battery for an energy storage system (ESS).

According to the present disclosure described above, it is possible to provide a method and an apparatus for charging and discharging lithium-ion battery capable of determining a charging/discharging section where aging of the lithium-ion battery can be minimized, and performing charging and discharging according to the determined section.

When the present disclosure is applied to a submarine battery, it is possible to expect a huge defense budget reduction effect by adjusting the submarine depot maintenance cycle in consideration of the battery life.

In addition, the present disclosure may be applied to an energy storage system (ESS) that operates charging and discharging according to a predetermined charging/discharging section.

The effects of the present disclosure are not limited to the above-mentioned effects, and other effects not mentioned will be clearly understood by those skilled in the art from the following description.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 shows discharge curves of an actual battery and a simulation battery.

FIG. 2 shows an overpotential measurement result for each discharge voltage of a simulation battery.

FIG. 3 is a table showing overpotential measurement results for each discharge voltage of a simulation battery.

FIG. 4 shows a change in SOH according to a charging/discharging section of a simulation battery

FIG. 5 shows the average of the SOH 80% reach time for each charge/discharge section of the simulation battery and the overpotential for each discharge voltage.

FIGS. 6A and 6B show an overpotential measurement result and an overpotential average measurement result for each discharge voltage of an actual battery.

FIG. 7 shows battery aging experiment conditions and plans of an actual battery.

FIG. 8 shows a battery aging test result of actual batteries.

FIG. 9 shows a comparison of battery aging test results of actual batteries

FIG. 10 is a block diagram of an apparatus for charging and discharging a lithium-ion battery according to an embodiment of the present disclosure.

FIG. 11 is a flowchart of a method for charging and discharging a lithium-ion battery according to an embodiment of the present disclosure.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

Hereinafter, preferred embodiments of the present disclosure will be described in detail with reference to the accompanying drawings. In the following description and the drawings, substantially identical components are denoted by the same reference numerals, and redundant explanations thereof will be omitted. In addition, in describing the present disclosure, detailed descriptions of well-known functions or configurations may be omitted when it is determined that such descriptions could obscure the gist of the present disclosure unnecessarily.

An overpotential of the lithium-ion battery is generated by a resistance of material movement generated during a lithium-ion electrodeposition/desorption process inside the battery (Jiwon Han, Dahee Jin, “A Review on the Deposition/Dissolution of Lithium Metal Anodes through Analyzing Overpotential Behaviors, Journal of the Korean Electrochemical Society,” Journal of the Korean Electrochemical Society, and vol. 25, No. 1, pp 1-12, 2022.). The inventors of the present disclosure performed an experiment to calculate an optimal charging and discharging section of the lithium-ion battery based on the results of the overpotential measurement of the lithium-ion battery and the battery aging measurement result, since the change in the overpotential of the lithium-ion battery may be related to the aging of the battery.

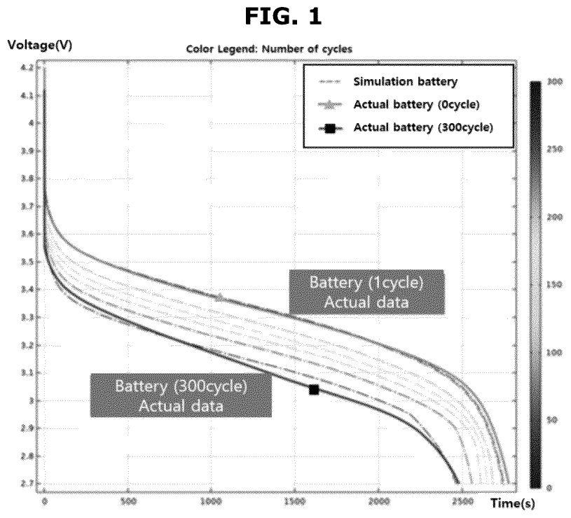

FIG. 1 shows discharge curves of an actual battery and a simulation battery. The 18650 battery was used as the actual battery, and the battery modeled with COMSOL simulation software based on the actual battery was used as the simulation battery. CC-CV (Constant Current, Constant Voltage) charging was performed with 1C-rate (2.6 A) up to a maximum voltage of 4.2V, and CC (Constant Current) discharging was performed up to a minimum discharge voltage of 2.7V. In FIG. 1, a triangular solid line represents an initial discharge curve of an actual battery, and a square solid line represents a discharge curve of an actual battery in which 300 cycles of aging have been performed. The dotted lines represent discharge curves of the simulation battery when aging is performed at 50 cycle intervals.

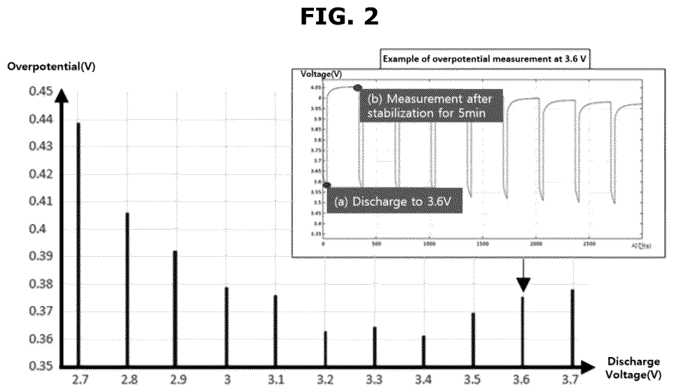

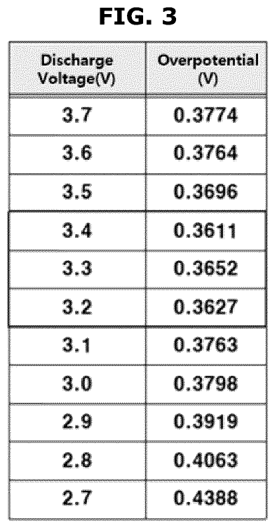

FIG. 2 shows an overpotential measurement result for each discharge voltage of a simulation battery. After charging up to SOC 100% (4.2V), pulse discharge was performed at 1C-rate (2.6 A) up to the corresponding discharge voltage for each discharge voltage, and a rest time of 5 minutes was provided for stabilization. As shown in (a), the discharge voltage and the open-circuit-voltage (OCV) measured after the stabilization for 5 minutes after the discharge of (b) was completed were measured, and the overpotential was measured through the difference between the corresponding discharge voltage and OCV. Through this, an overpotential was calculated for each discharge voltage of 3.7V, 3.6V, 3.5V, 3.4V, 3.3V, 3.2V, 3.1V, 3.0V, 2.9V, 2.8V, and 2.7V. FIG. 3 is a table showing overpotential measurement results for each discharge voltage of a simulation battery.

Referring to FIGS. 2 and 3, it can be seen that the overpotential value generally decreased in the discharge voltage 3.7V˜3.2V period, the overpotential value has a relatively small value in the 3.4V˜3.2V period, and the overpotential increases in the period below 3.2V. In consideration of the change in the overpotential, the change in the state of health (SOH) according to the charge/discharge SOC period or voltage of the battery was examined.

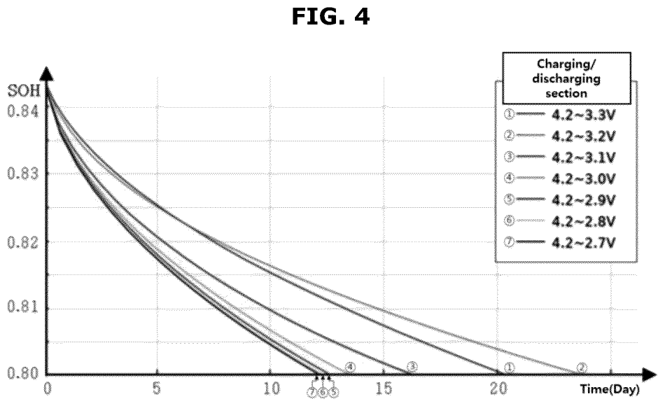

FIG. 4 shows a change in SOH according to a charging/discharging section of a simulation battery. As shown in FIG. 1, a section charge/discharge simulation was performed as follows using a simulation battery reflecting the aging characteristics of the actual battery. In the case of charging, in consideration of charging the SOC to nearly 100% in preparation for a contingency situation when snorkeling (charging) in the submarine, the CC-CV is charged to 4.2V, and the minimum discharge voltage is changed to 3.3V, 3.2V, 3.1V, 3.0V, 2.9V, 2.8V, and 2.7V by CC discharge during discharge, thereby calculating the change of SOH as shown in FIG. 4. Referring to FIG. 4, it may be seen that aging of the battery is minimized in the 4.2V˜3.2V charging/discharging period.

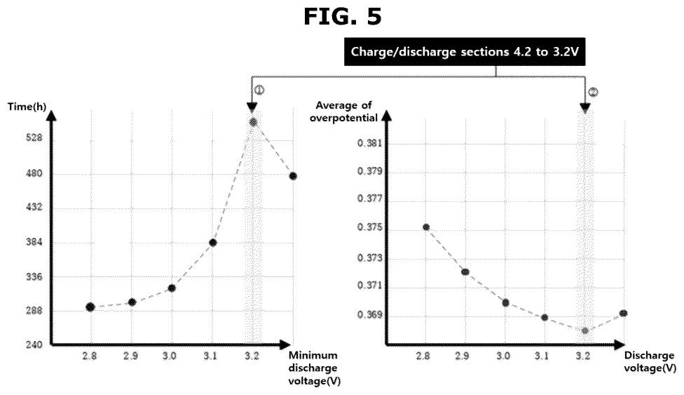

FIG. 5 shows the average of the SOH 80% reach time for each charge/discharge section of the simulation battery and the overpotential for each discharge voltage. The graph on the left of FIG. 5 shows the time until the SOH of the simulation battery reaches 80% for each minimum discharge voltage (based on aging of the submarine battery), and the graph on the right shows the average of the overpotential measured up to the corresponding discharge voltage for each discharge voltage of the simulation battery. Referring to FIG. 5, it can be seen that the time to reach SOH 80% becomes the maximum in the charge/discharge sections 4.2 to 3.2V according to the discharge voltage 3.2V at which the average of the overpotential becomes the minimum, and thus the battery aging is minimized.

As described above, it was confirmed through the COMSOL simulation that the discharge voltage at which the average of the overpotential is minimized and the charge/discharge section at which the battery aging is minimized correspond to each other, and the inventor verified this using an actual 18650 lithium-ion battery.

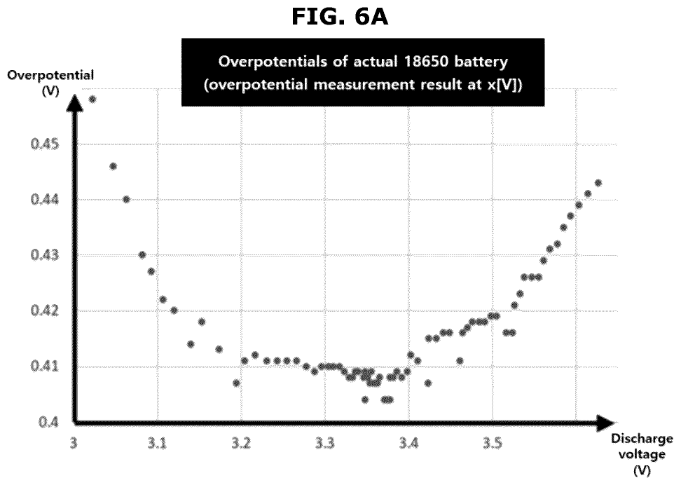

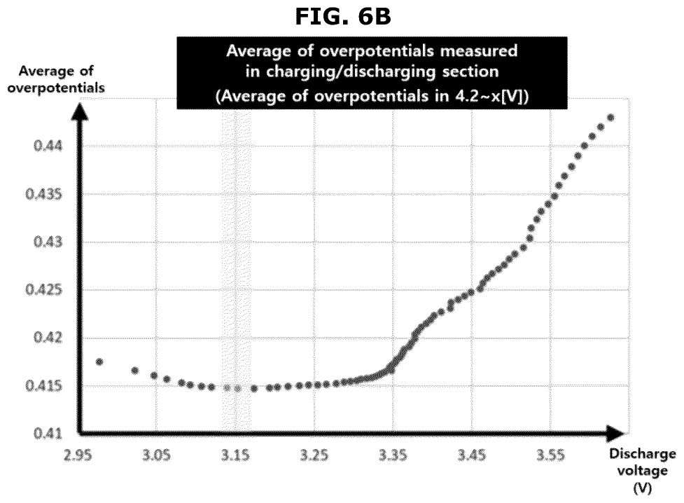

FIGS. 6A and 6B show an overpotential measurement result and an overpotential average measurement result for each discharge voltage of an actual battery. FIG. 6A shows an overpotential measurement result for each discharge voltage of an actual battery, and FIG. 6B shows an average of overpotentials measured up to a corresponding discharge voltage for each discharge voltage. Referring to FIG. 6B, it can be seen that the average overpotential reaches its minimum at a discharge voltage of 3.15 V.

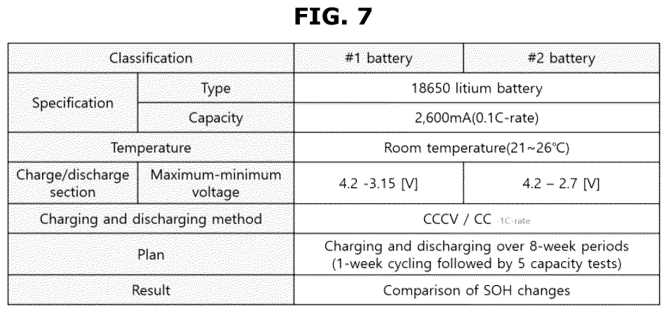

FIG. 7 shows battery aging experiment conditions and plans of an actual battery. For verification, as in the simulation, CC-CV charging was performed up to 4.2V during charging. During discharging, battery #1 was discharged at a constant current from the maximum voltage 4.2V to 3.15V, where the average value of the overpotential is the minimum, by using the overpotential measurement result of the actual battery of FIG. 6A, and battery #2 was discharged at a constant current from the maximum voltage 4.2V to 2.7V recommended by the manufacturer. For the experimental temperature, both batteries #1 and #2 were charged and discharged for 8 weeks at room temperature (21˜26° C.) under the same conditions, and a capacity test was performed 5 times a week.

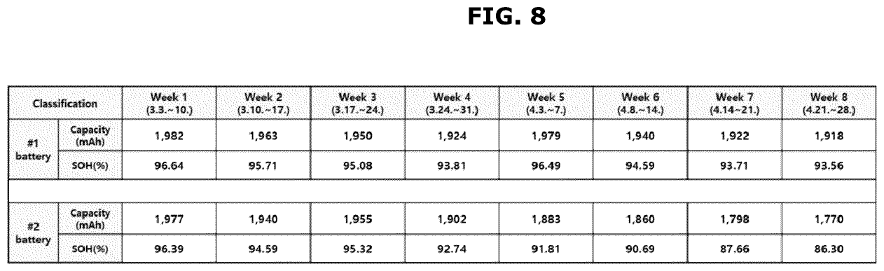

FIG. 8 shows a battery aging test result of actual batteries. Both batteries #1 and #2 had the same capacity of 2,051 mAh at the beginning, but after 8 weeks of aging, the SOH of battery #1 (charge/discharge section 4.2˜3.15V) was 1,918 mAh, which was 93.56%, and the SOH of battery #2 (charge/discharge section 4.2˜2.7V) was 1,770 mAh, which was 86.30%.

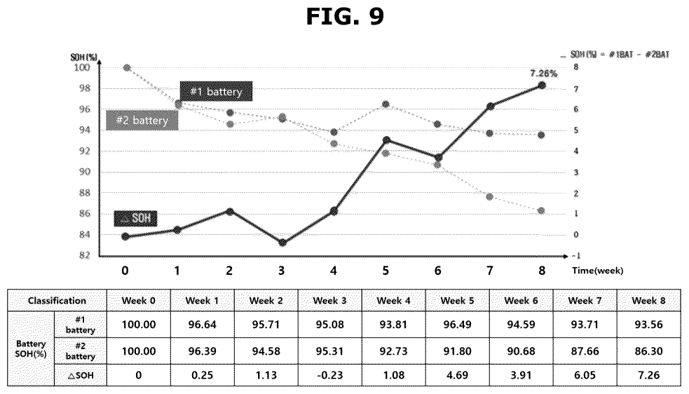

FIG. 9 shows comparison of battery aging test results of batteries #1 and #2. Referring to FIG. 9, it can be seen that battery #1, which has performed charging and discharging in the charge/discharge section 4.2˜3.15V in consideration of the overpotential measurement result of the battery, shows a SOH difference of about 7.26% for 8 weeks compared to battery #2, which has performed charging and discharging in the manufacturer's recommended charge/discharge section (4.2 to 2.7 V), thereby slowing battery aging.

As described above, the overpotential according to the SOC was measured during charging and discharging a lithium-ion battery, and it was confirmed that battery aging can be slowed if the charging and discharging is performed in the charge/discharge section where the average of the overpotential is relatively low.

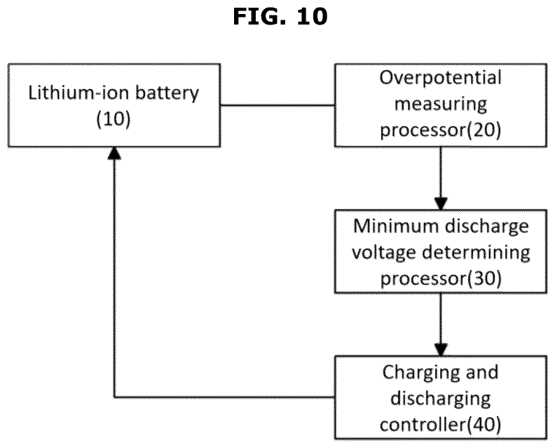

FIG. 10 is a block diagram of an apparatus for charging and discharging a lithium-ion battery according to an embodiment of the present disclosure.

The apparatus for charging and discharging according to an embodiment of the present disclosure includes a lithium-ion battery 10, an overpotential measuring processor 20, a minimum discharge voltage determining processor 30, and a charging and discharging controller 40.

The lithium-ion battery 10 may be a lithium-ion battery for a submarine or a lithium-ion battery for an energy storage system (ESS).

The overpotential measuring processor 20 charges the lithium-ion battery 10 to a maximum voltage and then measures an overpotential for each discharge voltage while discharging. Here, charging may be performed using Constant Current Constant Voltage (CC-CV) charging, and discharging may be performed using constant current (CC) discharging. When measuring the overpotential, the overpotential measuring processor 20 may discharge the lithium-ion battery 10 to a corresponding discharge voltage using pulse discharge, measure an open-circuit-voltage (OCV) after a predetermined rest time, and measure the overpotential based on the difference between the corresponding discharge voltage and OCV.

The minimum discharge voltage determining processor 30 determines the minimum discharge voltage for controlling charging and discharging based on the overpotential measurement result of the overpotential measurement processor 20. Specifically, the minimum discharge voltage determining processor 30 may calculate an average of overpotentials measured from the maximum voltage to the corresponding discharge voltage for each discharge voltage, and determine the discharge voltage at which the average of the overpotentials is minimized as the minimum discharge voltage for controlling charging and discharging.

The charging and discharging controller 40 is for controlling charging and discharging the lithium-ion battery 10 according to the minimum discharge voltage determined by the minimum discharge voltage determining processor 30. That is, the charging and discharging controller 40 charges the lithium-ion battery 10 whenever the discharge voltage reaches the lowest discharge voltage determined by the lowest discharge voltage determining processor 30 during the operation of the lithium-ion battery 10.

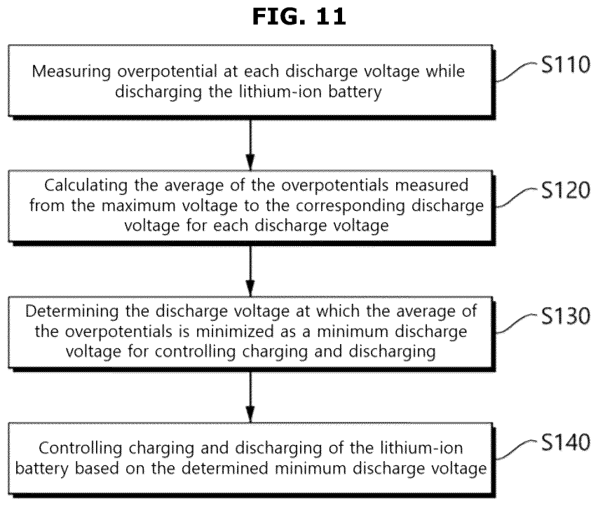

FIG. 11 is a flowchart of a method for charging and discharging a lithium-ion battery according to an embodiment of the present disclosure.

In step S110, the lithium-ion battery 10 is charged to a maximum voltage and then discharged to measure an overpotential for each discharge voltage. Here, charging may be performed using Constant Current Constant Voltage (CC-CV) charging, and discharging may be performed using constant current (CC) discharging. When measuring the overpotential, the lithium-ion battery 10 may be discharged to a corresponding discharge voltage by using pulse discharge, and an open circuit-voltage (OCV) may be measured after a predetermined rest time, and the overpotential may be measured based on the difference between the corresponding discharge voltage and OCV.

In step S120, the average of the overpotentials measured from the maximum voltage to the corresponding discharge voltage for each discharge voltage is calculated.

In step S130, the discharge voltage at which the average of the overpotentials is minimized is determined as the minimum discharge voltage for controlling charging and discharging.

In step S140, charging and discharging of the lithium-ion battery 10 is controlled according to the minimum discharge voltage determined in step S130. That is, the lithium-ion battery 10 is charged whenever the discharge voltage reaches the minimum discharge voltage determined through step S130 during the operation of the lithium-ion battery 10.

The embodiments of the present disclosure may be represented as functional block configurations and various processing steps. These functional blocks may be implemented by various numbers of hardware and/or software components that perform specific functions. For example, the embodiments may employ integrated circuit components such as memory, processing units, logic, or look-up tables capable of executing various functions under the control of one or more microprocessors or other control devices. Similar to how elements of the present disclosure may be implemented through software programming or software modules, the embodiments may also be implemented in programming or scripting languages such as C, C++, Java, assembler, or the like, including various algorithms realized as combinations of data structures, processes, routines, or other programming constructs. Functional aspects may be implemented as algorithms executed by one or more processors. Furthermore, the embodiments may incorporate conventional technologies for environmental configuration, signal processing, and/or data processing. The terms such as “mechanism,” “element,” “means,” or “configuration” may be used in a broad sense and are not limited to mechanical or physical implementations. These terms may include a series of software routines, particularly in association with a processor or similar component.

Specific implementations described in the embodiments are merely exemplary, and in no way limit the scope of the embodiments. For the sake of conciseness, descriptions of conventional electronic components, control systems, software, and other functional aspects of such systems may be omitted. In addition, lines or connection members illustrated between components in the drawings are intended to represent functional and/or physical or circuit connections by way of example, and such connections may be replaced or supplemented with various other functional, physical, or circuit connections in actual implementations. Furthermore, unless explicitly described as being “essential,” “critical,” or the like, a given component may not be necessary for the implementation of the present disclosure.

The present disclosure has been described above with reference to preferred embodiments. However, it will be understood by those skilled in the art that various modifications and variations can be made without departing from the essential spirit and scope of the present disclosure. Therefore, the disclosed embodiments should be considered illustrative rather than limiting. The scope of the present disclosure is defined by the claims, and all variations and equivalents that fall within the scope of the claims should be interpreted as being included in the present disclosure.

What is claimed is:

1. A method for charging and discharging a lithium-ion battery, the method comprising:
measuring an overpotential for each discharge voltage while discharging the lithium-ion battery;
determining a minimum discharge voltage for controlling charging and discharging based on a measurement result of the overpotential; and
controlling charging and discharging the lithium-ion battery according to the determined minimum discharge voltage.

2. The method for charging and discharging of claim 1,
wherein the measuring an overpotential comprises discharging the lithium-ion battery using pulse discharge.

3. The method for charging and discharging of claim 2,
wherein the measuring an overpotential comprises:
discharging the lithium-ion battery to a corresponding discharge voltage using pulse discharge;
measuring an open-circuit-voltage (OCV) after a predetermined rest time; and
measuring the overpotential based on the difference between the corresponding discharge voltage and the OCV.

4. The method for charging and discharging of claim 1,
wherein the determining a minimum discharge voltage comprises:
calculating an average of overpotentials measured up to a corresponding discharge voltage for each discharge voltage; and
determining a discharge voltage at which the average of the overpotentials is minimized as the minimum discharge voltage for controlling charging and discharging.

5. The method for charging and discharging of claim 1,
wherein the lithium-ion battery is a lithium-ion battery for a submarine.

6. The method for charging and discharging of claim 1,
wherein the lithium-ion battery is a lithium-ion battery for an energy storage system (ESS).

7. An apparatus for charging and discharging a lithium-ion battery, the apparatus comprising:
an overpotential measuring processor configured to measure an overpotential for each discharge voltage while discharging the lithium-ion battery;
a minimum discharge voltage determining processor configured to determine a minimum discharge voltage for controlling charging and discharging based on a measurement result of the overpotential; and
a charging and discharging controller configured to control charging and discharging the lithium-ion battery according to the determined minimum discharge voltage.

8. The apparatus for charging and discharging of claim 7,
wherein the overpotential measuring processor is configured to discharge the lithium-ion battery using pulse discharge.

9. The apparatus for charging and discharging of claim 8,
wherein the overpotential measuring processor is configured to discharge the lithium-ion battery to a corresponding discharge voltage using pulse discharge, measure an open-circuit-voltage (OCV) after a predetermined rest time, and measure the overpotential based on the difference between the corresponding discharge voltage and the OCV.

10. The apparatus for charging and discharging of claim 7,
wherein the minimum discharge voltage determining processor is configured to calculate an average of overpotentials measured up to a corresponding discharge voltage for each discharge voltage, and determine a discharge voltage at which the average of the overpotentials is minimized as the minimum discharge voltage for controlling charging and discharging.

11. The apparatus for charging and discharging of claim 7,
wherein the lithium-ion battery is a lithium-ion battery for a submarine.

12. The apparatus for charging and discharging of claim 7,
wherein the lithium-ion battery is a lithium-ion battery for an energy storage system (ESS).
